(19) United States
(12) Patent Application Publication
(10) Pub. No.: US 2024/0009938 A1
(43) Pub. Date: Jan. 11, 2024

(54) APPARATUS FOR MANUFACTURING DISPLAY APPARATUS AND METHOD OF MANUFACTURING DISPLAY APPARATUS

(71) Applicant: Samsung Display Co., Ltd., Yongin-si (KR)

(72) Inventor: Changook Lee, Yongin-si (KR)

(21) Appl. No.: 18/304,146

(22) Filed: Apr. 20, 2023

(30) Foreign Application Priority Data
Jul. 11, 2022 (KR) 10-2022-0085273

(51) Int. Cl. B29C 65/78; B29C 65/80

(52) U.S. Cl. CPC B29C 65/7844; B29C 65/80; B29L 2031/3475

(57) ABSTRACT

An apparatus for manufacturing a display apparatus is provided. The apparatus includes: a first seat portion configured to receive a first member; a second seat portion arranged to face the first seat portion and configured to receive a second member; a roller portion adjacent to a second side of the second seat portion; a rail groove in one surface of the second seat portion facing the first seat portion; and an adsorber inside the rail groove and configured to adsorb the second member.

### CROSS-REFERENCE TO RELATED APPLICATION

This application claims priority to and the benefit of Korean Patent Application No. 10-2022-0085273, filed on Jul. 11, 2022, in the Korean Intellectual Property Office, the entire disclosure of which is incorporated herein by reference.

### BACKGROUND

### 1. Field

Aspects of embodiments of the present disclosure relate to an apparatus for manufacturing a display apparatus and a method of manufacturing a display apparatus.

### 2. Description of the Related Art

A display apparatus may be formed (or manufactured) by the coupling of various members. For example, a display apparatus may be formed by coupling a display panel including light-emitting elements to a cover window for protecting the display panel. The coupling of the display panel to the cover window may be performed by a vacuum bonding method or by a pressing method using a roller.

### SUMMARY

In an apparatus for manufacturing a display apparatus and a method of manufacturing a display apparatus according to the related art, members to be attached are detached from positions set in advance during an attaching process.

Embodiments of the present disclosure include a display apparatus providing a reduced defect occurrence possibility (e.g., a reduced rate of defects) during a manufacturing process, and a method of manufacturing a display apparatus. However, such a feature is merely an example, and the present disclosure is not limited thereto.

Additional aspects and features of the present disclosure will be set forth, in part, in the description which follows and, in part, will be apparent from the description or may be learned by practice of the presented embodiments of the present disclosure.

According to an embodiment of the present disclosure, an apparatus for manufacturing a display apparatus is provided. The apparatus includes: a first seat portion configured to receive a first member; a second seat portion arranged to face the first seat portion and configured to receive a second member; a roller portion adjacent to a second side of the second seat portion; a rail groove in one surface of the second seat portion facing the first seat portion; and an adsorber inside the rail groove and configured to adsorb the second member.

The second seat portion may have a first side and the second side. The first side may be arranged in an opposite direction of the roller portion, and the second side may be arranged in a direction of the roller portion. The rail groove may extend in a direction from the first side to the second side.

The rail groove may have a first inner side and a second inner side. The first inner side may be arranged in an opposite direction of the roller portion, and the second inner side may be arranged in a direction of the roller portion.

The adsorber may be configured to move in a direction from the first inner side to the second inner side.

When the adsorber contacts the second inner side, the adsorber may be configured to detach from the second member.

The adsorber may be configured to slide in a direction from the first inner side to the second inner side.

The roller portion may extend in a first direction and may be configured to move in a second direction crossing the first direction under the second member. The rail groove may extend in the second direction.

The second seat portion may be configured to move in the second direction under the second member.

The roller portion may extends in a first direction, the adsorber may be provided in plurality, and the plurality of adsorbers may be spaced apart from each other in the first direction and arranged inside the rail groove.

The roller portion may extend in a first direction, the rail groove may be provided in plurality, the plurality of rail grooves may be spaced apart from each other in a second direction crossing the first direction and are in the one surface of the second seat portion facing the first seat portion, the adsorber may be provided in plurality, and each of the plurality of adsorbers may be inside the plurality of rail grooves.

According to another embodiment of the present disclosure, a method of manufacturing a display apparatus is provided. The method includes: arranging a first member under a first seat portion; arranging a second member on a second seat portion to face the first seat portion; adsorbing the second member onto an adsorber inside a rail groove in the second seat portion; tilting the second seat portion to form an angle with respect to the first seat portion; and attaching the second member to the first member by pressing the second member by using a roller portion. The adsorber moves along the rail groove as the second member is attached to the first member.

The attaching of the second member may include pressing the first member and the second member while moving the roller portion under the second member.

The method may further include moving the second seat portion under the second member in a same direction as a moving direction of the roller portion.

The adsorber may move inside the rail groove as the second seat portion is moved.

The rail groove may extend in a same direction as a moving direction of the roller portion, and the rail groove may have a first inner side and a second inner side. The first inner side may be arranged in an opposite direction of the roller portion, and the second inner side may be arranged in a direction of the roller portion.

The adsorber may move inside the rail groove in a direction from the first inner side to the second inner side along the rail groove.

The adsorber may slide along the rail groove in a direction from the first inner side to the second inner side of the rail groove.

The method may further include detaching the second member from the adsorber; and attaching a portion of the second member detached from the adsorber to the first member.

The portion of the second member detached from the adsorber may be attached to the first member after the adsorber has moved along the rail groove.

The rail groove may extend in a same direction as a moving direction of the roller portion in a plan view. The rail groove may have a first inner side and a second inner side. The first inner side may be arranged in an opposite direction of the roller portion, and the second inner side may be arranged in a direction of the roller portion. The portion of the second member detached from the adsorber may be attached to the first member after the adsorber contacts the second inner side.

These and/or other aspects and features of the present disclosure will become apparent and more readily appreciated from the following description of the embodiments, the accompanying drawings, and claims.

### BRIEF DESCRIPTION OF THE DRAWINGS

The above and other aspects and features of embodiments of the present disclosure will be more apparent from the following description, taken in conjunction with the accompanying drawings, in which:

FIG. 1 is a schematic perspective view of an apparatus for manufacturing a display apparatus according to an embodiment;

FIG. 2 is a schematic cross-sectional view of a portion of an apparatus for manufacturing a display apparatus according to an embodiment;

FIG. 3 is a schematic plan view of a portion of an apparatus for manufacturing a display apparatus according to an embodiment;

FIGS. 4 to 7 are cross-sectional views showing steps of a method of manufacturing a display apparatus by using the apparatus for manufacturing a display apparatus shown in FIG. 1;

FIG. 8 is a schematic plan view of a portion of an apparatus for manufacturing a display apparatus according to another embodiment;

FIG. 9 is a schematic plan view of a portion of an apparatus for manufacturing a display apparatus according to another embodiment;

FIG. 10 is a schematic plan view of a portion of an apparatus for manufacturing a display apparatus according to another embodiment;

FIG. 11 is a schematic perspective view of a portion of a display apparatus manufactured by an apparatus for manufacturing a display apparatus according to an embodiment; and

FIG. 12 is a schematic cross-sectional view taken along the line II-II′ of FIG. 11 of the display apparatus shown in FIG. 11.

### DETAILED DESCRIPTION

Reference will now be made in detail to embodiments, examples of which are illustrated in the accompanying drawings. In this regard, the described embodiments may have different forms and should not be construed as being limited to the descriptions set forth herein. Accordingly, embodiments are merely described below, by referring to the figures, to explain aspects and features of the present description.

As the present disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements except where expressly described otherwise. As used herein, the term “and/or” includes any and all combinations of one or more of the associated listed items. Further, the use of “may” when describing embodiments of the present disclosure relates to “one or more embodiments of the present disclosure.” Expressions, such as “at least one of,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When a certain embodiment may be implemented differently, a specific process order may be performed in the order different from the described order. As an example, two processes successively described may be concurrently or simultaneously performed substantially or performed in the opposite order.

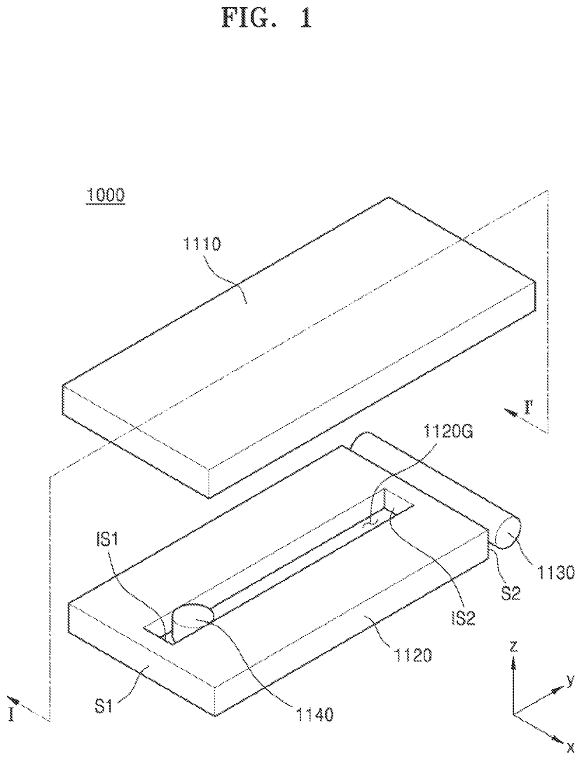

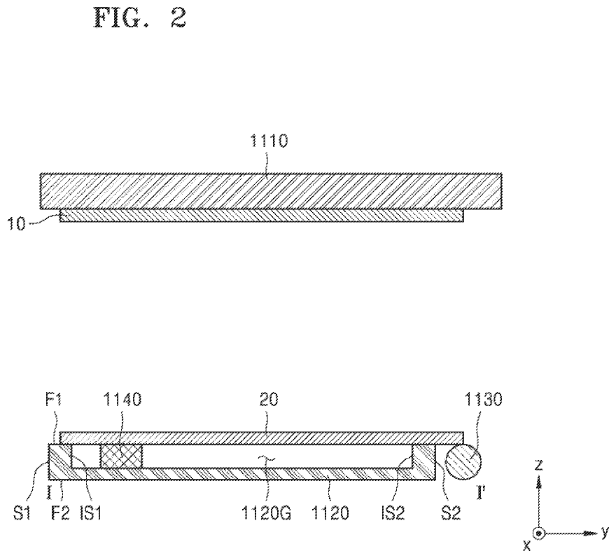

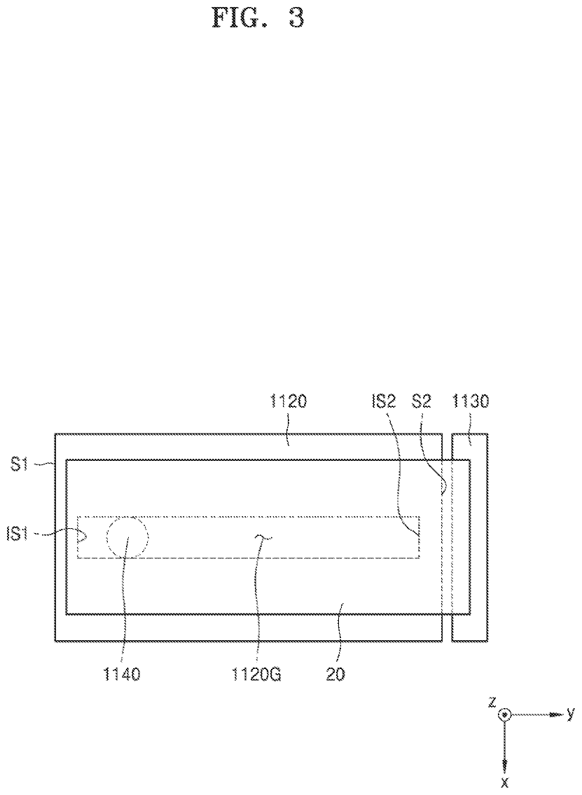

FIG. 1 is a schematic perspective view of an apparatus 1000 for manufacturing a display apparatus according to an embodiment, FIG. 2 is a schematic cross-sectional view of a portion of the apparatus 1000 for manufacturing a display apparatus according to an embodiment, and FIG. 3 is a schematic plan view of a portion of the apparatus 1000 for manufacturing a display apparatus according to an embodiment. For convenience of description, FIG. 2 shows a first member 10 and a second member 20. For convenience of illustration, FIG. 2 shows only a second seat portion 1120, a roller portion 1130, and an adsorber 1140 included in the apparatus 1000 for manufacturing a display apparatus. For convenience of description, FIG. 3 shows the second member 20 together.

Referring to FIGS. 1 to 3, the apparatus 1000 for manufacturing a display apparatus may include a first seat portion 1110, the second seat portion 1120, the roller portion 1130, a rail groove 1120G, and the adsorber 1140.

The first member 10 may be seated on the first seat portion 1110. For example, the first seat portion 1110 may be configured to fix the first member 10 by using various methods. As an example, the first seat portion 1110 may include a vacuum chuck to fix the first member 10 thereon. In another embodiment, the first seat portion 1110 may include an adhesive chuck for fixing the first member 10 thereon. In another embodiment, the first seat portion 1110 may include an electrostatic chuck for fixing the first member 10 thereon.

The first member 10 may be rigid. As an example, the first member 10 may include a cover window. The cover window may be configured to protect an upper surface of a display panel. As an example, the cover window may be arranged to cover the upper surface of the display panel and configured to protect the upper surface of the display panel. Herein, the “upper” surface of the display panel may be defined as a surface facing a direction in which the display panel is configured to display images. The cover window may include glass, sapphire (e.g., Al₂O₃), or plastic. As an example, the cover window may be an ultra-thin glass (UTG®, a registered trademark of Samsung Electronics Co., Ltd.) strengthened by a method such as chemical strengthening or thermal strengthening. However, the present disclosure is not limited thereto. In another embodiment, the first member 10 may be flexible or bendable.

The second seat portion 1120 may be arranged to face the first seat portion 1110. During a process of manufacturing the display apparatus, the second seat portion 1120 may be tilted to have (or to form) an angle (e.g., a preset or predetermined angle) with respect to the first seat portion 1110. The second seat portion 1120 may be tilted by a driver.

The second member 20 may be seated on the second seat portion 1120. The second seat portion 1120 may have an edge extending in a first direction (e.g., an x direction or a −x direction in the drawings), and an edge extending in a second direction (e.g., a y direction or a −y direction in the drawings). The first direction and the second direction may be directions crossing each other. As an example, an angle formed between the first direction and the second direction may be an acute angle. In other embodiments, an angle formed between the first direction and the second direction may be an obtuse angle or a right angle. Hereinafter, for convenience of description, an embodiment in which an angle formed between the first direction and the second direction is a right angle is primarily described.

The second member 20 may be rigid. As an example, the second member 20 may include a display panel. The display panel may be configured to display images by using a two-dimensionally arranged array of a plurality of pixels. The display panel may include a substrate and a light-emitting element disposed over (or on) the substrate. Though the light-emitting element may include, for example, an inorganic light-emitting diode or an organic light-emitting diode, the kind of the light-emitting diode is not limited thereto. The substrate of the display panel may include glass, sapphire (e.g., Al₂O₃), or plastic. As an example, the substrate of the display panel may be an ultra-thin glass (UTG®, a registered trademark of Samsung Electronics Co., Ltd.) strengthened by a method such as chemical strengthening or thermal strengthening. However, the present disclosure is not limited thereto. In another embodiment, the second member 20 may be flexible or bendable.

One of the first seat portion 1110 and the second seat portion 1120 may be disposed over the other of the first seat portion 1110 and the second seat portion 1120. Hereinafter, for convenience of description, the case where the first seat portion 1110 is disposed higher than the second seat portion 1120 is mainly described.

The apparatus 1000 for manufacturing the display apparatus may further include a driver. The driver may be connected to at least one of the first seat portion 1110 and the second seat portion 1120 and may move the at least one of the first seat portion 1110 and the second seat portion 1120. Hereinafter, for convenience of description, an embodiment in which the driver is connected to the second seat portion 1120 is primarily described.

The driver may be connected to the second seat portion 1120 and may allow (e.g., may move) the second seat portion 1120 to approach the first seat portion 1110 or to move away from (e.g., to be separated from) the first seat portion 1110. In some embodiments, the driver may move the second seat portion 1120 in the first direction (e.g., an x direction or a −x direction) and/or the second direction (e.g., a y direction or a −y direction). In some embodiments, the driver may tilt the second seating portion 1120. In some embodiments, when the second seat portion 1120 is tilted, the driver may allow (e.g., may move) the second seat portion 1120 to approach the first seat portion 1110 or to move away from (e.g., to be separated from) the first seat portion 1110. In some embodiments, when the second seat portion 1120 is tilted, the driver may move the second seat portion 1120 in the first direction (e.g., the x direction or the −x direction) and/or the second direction (e.g., the y direction or the −y direction). In an embodiment, the driver may include a motor connected to a cylinder, a linear motor, a ball screw, or a motor connected to the ball screw. However, the driver is not limited thereto and may include all structures and all apparatuses configured to linearly move and/or rotationally move the second seat portion 1120. The apparatus 1000 for manufacturing the display apparatus may further include a controller configured to control the driver.

The roller portion 1130 may be disposed to be adjacent to one side of the second seat portion 1120. The roller portion 1130 may have a circular cross-section and may extend in the first direction (e.g., the x direction or the −x direction). For example, the roller portion 1130 may have a cylindrical shape extending in the first direction (e.g., the x direction or the −x direction). However, the present disclosure is not limited thereto. As an example, the roller portion 1130 may have a cylindrical shape extending in the second direction (e.g., the y direction or the −y direction). Hereinafter, for convenience of description, an embodiment in which the roller portion 1130 has a cylindrical shape extending in the first direction (e.g., the x direction or the −x direction) is primarily described.

The roller portion 1130 may press the second member 20 and attach the second member 20 to the first member 10. For example, the roller portion 1130 may press the second member 20 in the direction of the first member 10 while moving along one surface of the second member 20. For example, the roller portion 1130 may press the second member 20 in the direction of the first member 10 while moving in the second direction (e.g., the y direction or the −y direction) crossing the first direction (e.g., the x direction or the −x direction) under the second member 20 to attach the second member 20 to the first member 10. A roller portion-driver, such as a motor configured to move the roller portion 1130, may be connected to the roller portion 1130. The controller may be configured to control a roller portion-controller.

As shown in FIGS. 1 to 3, the rail groove 1120G may be disposed in (e.g., recessed from) one surface of the second seat portion 1120. For example, the rail groove 1120G may be disposed in one surface of the second seat portion 1120 facing the first seat portion 1110. As an example, the second seat portion 1120 may have a first surface F1 and a second surface F2. The first surface F1 faces the first seat portion 1110, and the second surface F2 is an opposite surface of the first surface F1. The rail groove 1120G may be disposed in (e.g., recessed from) the first surface F1 of the second seat portion 1120. For example, the rail groove 1120G may be disposed in one surface of the second seat portion 1120 contacting the second member 20.

The rail groove 1120G may extend from one side (e.g., one end) to another side (e.g., another end) of the second seat portion 1120. For example, the rail groove 1120G may extend in the second direction (e.g., they direction or the −y direction) crossing the first direction (e.g., the x direction or the −x direction). As an example, the second seat portion 1120 may include a first side (e.g., a first end or edge) S1 and a second side (e.g., a second end or edge) S2. The first side S1 is arranged in the opposite direction of (e.g., is opposite to) the roller portion 1130, and the second side S2 is arranged in the direction of (e.g., adjacent to) the roller portion 1130. The rail groove 1120G may extend in the direction from the first side S1 to the second side S2. For example, the rail groove 1120G may extend in the same direction as the moving direction of the roller portion 1130. However, the present disclosure is not limited thereto. As an example, the rail groove 1120G may extend in the first direction (e.g., the x direction or the −x direction).

An adsorber 1140 may be disposed in the rail groove 1120G. The adsorber 1140 may move inside (e.g., along) the rail groove 1120G. For example, the adsorber 1140 may move in the direction from the first side S1 to the second side S2. As an example, the rail groove 1120G may have a first inner side (e.g., a first inner end or edge) 151 and a second inner side (e.g., a second inner end or edge) 152. The first inner side 151 is arranged in the opposite direction of the roller portion 1130, and the second inner side IS2 is arranged in the direction of the roller portion 1130. The first inner side IS1 may be relatively adjacent to the first side S1, and the second inner side IS2 may be relatively adjacent to the second side S2. The adsorber 1140, arranged to be adjacent to the first inner side IS1, may be configured to move to be relatively close to the second inner side IS2 inside the rail groove 1120G. In other words, the adsorber 1140 may be configured to move (e.g., slide) in the direction from the first inner side IS1 to the second inner side IS2 inside the rail groove 1120G.

The adsorber 1140 may adsorb the second member 20 such that the second member 20 may be fixed on the adsorber 1140 and seated on the second seat portion 1120. For example, the adsorber 1140 may be adsorbed on the rear surface of the second member 20. For this purpose, the adsorber 1140 may include an adsorption member, such as a vacuum pad. The vacuum pad is not particularly limited and any suitable vacuum pad may be used that is generally used for adsorption of a target object. As an example, the vacuum pad may include porous rubber or porous aluminum.

The adsorber 1140 that adsorbs the second member 20 may be configured to move to a second position (e.g., a preset position) inside the rail groove 1120G. For example, the adsorber 1140 may be configured to move to the second position inside the rail groove 1120G by sliding in the direction from the first inner side IS1 (e.g., from a first or initial position) to the second inner side IS2 along the rail groove 1120G. As the adsorber 1140 moves, the second member 20, which is fixed on the adsorber 1140, may be moved in the direction from the first side S1 to the second side S2 on the second seat portion 1120. Accordingly, the second member 20 may be moved to the second position on the second seat portion 1120 by the adsorber 1140. Because the second member 20 is configured to move to the second position on the second seat portion 1120, the adsorber 1140 may be moved to the second position inside the rail groove 1120G by the second member 20.

An adhesive member may be disposed on the second member 20. As an example, the adhesive member may include at least one of an optical clear resin (OCR), an optical clear adhesive (OCA), and a pressure sensitive adhesive (PSA). The second member 20 may be attached to the first member 10 by the adhesive member. Though it is shown in FIGS. 2 and 3 that the first member 10 and the second member 20 are flat, the present disclosure is not limited thereto. As an example, the first member 10 and/or the second member 20 may each have a curvature.

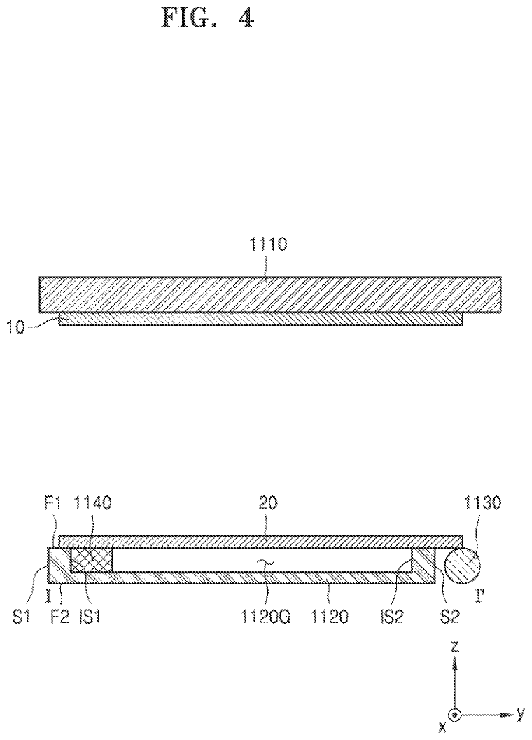

The apparatus 1000 for manufacturing the display apparatus may further include a vision portion configured to photograph the position of at least one of the first member 10 and the second member 20. In addition, the apparatus 1000 for manufacturing the display apparatus may further include (or may be arranged in) a chamber in which the first seat portion 1110, the second seat portion 1120, the roller portion 1130, the rail groove 1120G, and the adsorber 1140 are disposed. Hereinafter, a method of manufacturing a display apparatus by using the apparatus 1000 for manufacturing the display apparatus is described in more detail. FIGS. 4 to 7 are cross-sectional views showing the method of manufacturing a display apparatus by using the apparatus 1000 for manufacturing a display apparatus shown in FIG. 1.

First, as shown in FIG. 4, the first member 10 may be seated on the first seat portion 1110, and the second member 20 may be seated on the second seat portion 1120. For example, the first member 10 may be disposed under the first seat portion 1110, and the second member 20 may be disposed on the second seat portion 1120 to face the first member 10. A portion (e.g., a first portion) of the second member 20 may be disposed on the second seat portion 1120, and another portion (e.g., a second portion) of the second member 20 may be disposed to protrude beyond the second side S2 of the second seat portion 1120 toward the roller portion 1130. Because the second member 20 is biased to the direction of the roller portion 1130 and disposed on the second seat portion 1120, another portion of the second member 20 may not be disposed on (e.g., may protrude from) the second seat portion 1120. The roller portion 1130 may be disposed under the second member 20. For example, the roller portion 1130 may be disposed under the portion (e.g., the second portion) of the second member 20 protruding past (or beyond or farther than) the second side S2 of the second seat portion 1120. As shown in FIG. 4, the adsorber 1140 may be disposed to be adjacent to the first inner side IS1 of the rail groove 1120G arranged in the opposite direction of the roller portion 1130. The adsorber 1140 may allow the second member to be disposed on the second seat portion 1120 by adsorbing the second member by using the vacuum pad and the like.

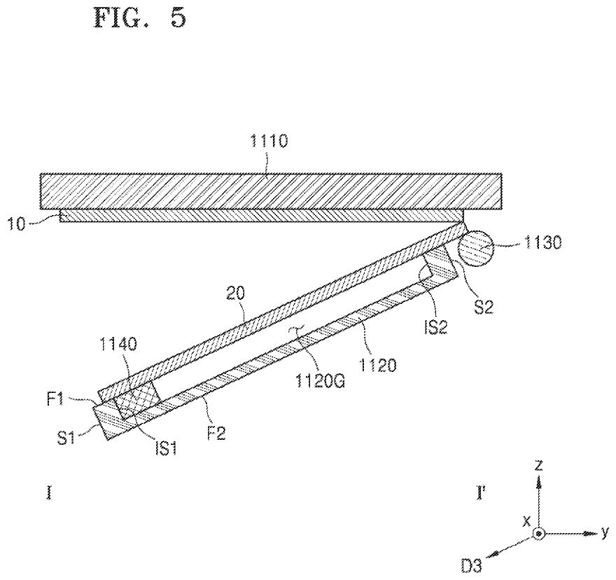

Subsequently, as shown in FIG. 5, the second seat portion 1120 may be tilted. For example, the second seat portion 1120 may be tilted such that the second seat portion 1120 forms an angle (e.g., a preset or predetermined angle) with respect to the first seat portion 1110. Because the first member 10 is seated on the first seat portion 1110 and the second member 20 is seated on the second seat portion 1120, the second member 20 may form an angle with respect to the first member 10. Accordingly, a distance between one side of the second member 20 and one side of the first member 10 corresponding thereto may be reduced. One side (e.g., one edge or end) of the second member 20 may be disposed to contact or to be adjacent to one side (e.g., one edge or end) of the first member 10 corresponding thereto. For example, a second side of the second member 20 (e.g., a second side of the second member 20 nearest to the second side S2 of the second seat portion 1120) may be disposed to be adjacent to one side of the first member 10 corresponding to the second side of the second member 20. When the second seat portion 1120 is tilted, the rail groove 1120G disposed in the first surface F1 of the second seat portion 1120 may be also tilted. Accordingly, the rail groove 1120G may extend in a third direction (e.g., a direction between the −y direction and the −z direction, that is, a direction D3). In other words, the rail groove 1120G may extend in the same direction as the moving direction of the roller portion 1130 in a plan view.

The degree of tilting the second seat portion 1120 and the second member 20 may vary depending on the type and/or shape of the first member 10 and the second member 20. Though it is shown in FIG. 5 that the second seat portion 1120 is tilted, the present disclosure is not limited thereto. As an example, the first member 10 may be tilted such that the second member 20 forms an angle (e.g., a preset or predetermined angle) with respect to the first member 10. In some embodiments, the first member 10 and the second member 20 may be tilted such that the second member 20 forms an angle (e.g., a preset or predetermined angle) with respect to the first member 10.

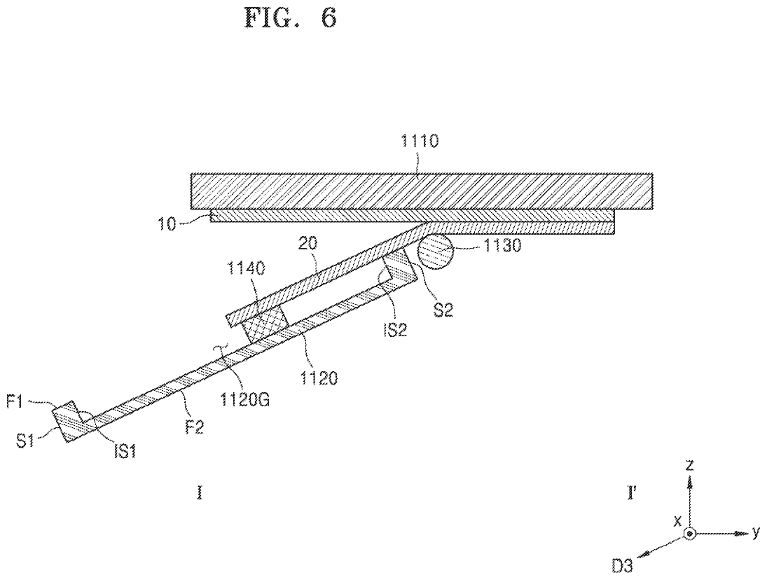

Subsequently, as shown in FIG. 6, the second member 20 may be attached to the first member 10 by moving the roller portion 1130 under the second member 20. For example, the roller portion 1130 may move in the direction from one side (e.g., the second side) of the second member 20 to another side of the second member 20 under the second member 20. As an example, the roller portion 1130 may be configured to move in the −y direction under the second member 20. The roller portion 1130 may simultaneously (or concurrently) press the first member 10 and the second member 20 together. As described above, the adhesive member may be disposed on the second member 20. As an example, the adhesive member may include at least one of an optical clear resin (OCR), an optical clear adhesive (OCA), and a pressure sensitive adhesive (PSA). The second member 20 may be attached to the first member by using the adhesive member.

Together with the moving of the roller portion 1130 under the second member 20, the second seat portion 1120 may be configured to move. For example, the second seat portion 1120 may be configured to move in the same direction as the moving direction of the roller portion 1130 under the second member 20. As an example, when the roller portion 1130 moves in the −y direction under the second member 20, the second seat portion 1120 may move in the −y direction under the second member 20.

As shown in FIG. 6, the adsorber 1140 may be configured to move in the direction from the first inner side IS1 to the second inner side IS2 inside the rail groove 1120G. As the second member 20 is attached to the first member 10 by moving the roller portion 1130 under the second member 20, the moving of the adsorber 1140 adsorbed to the second member 20 may be limited. Thus, when the second seat portion 1120 moves in the y direction under the second member 20, the adsorber 1140 may move in the direction from the first inner side IS1 to the second inner side IS2 inside the rail groove 1120G. In other words, the adsorber 1140 may be configured to slide in the direction from the first inner side IS1 to the second inner side IS2 inside the rail groove 1120G.

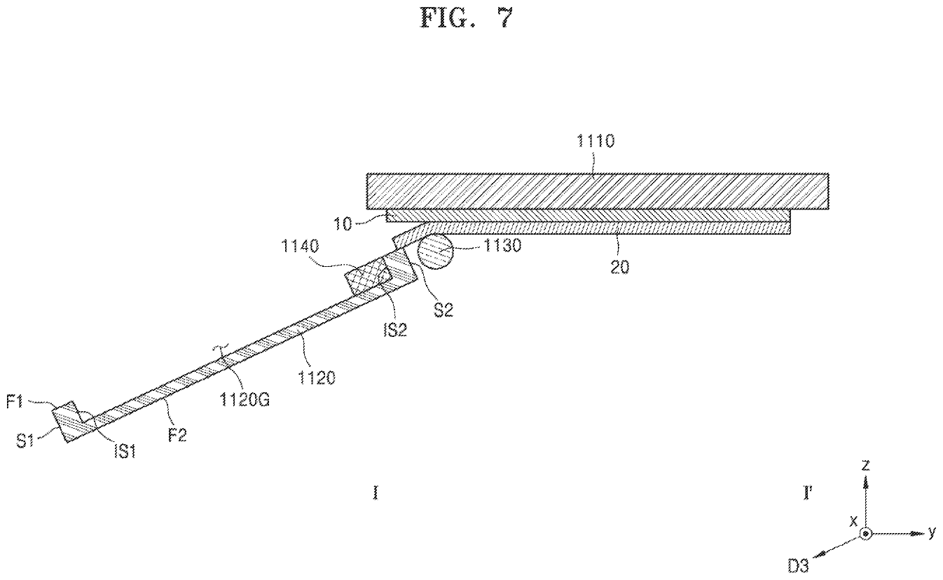

Subsequently, as shown in FIG. 7, when the adsorber 1140 contacts the second inner side IS2, the second member 20 may detach from the adsorber 1140. Accordingly, the roller portion 1130 may move to a rear surface of the portion of the second member 20 that has been directly adsorbed by the adsorber 1140. Accordingly, because the roller portion 1130 presses the portion of the second member 20 that has been directly adsorbed by the adsorber 1140 and the portion of the first member 10 corresponding thereto, the portion of the second member 20 that has been directly adsorbed by the adsorber 1140 may be attached to the first member 10. In other words, because the roller portion 1130 presses the portion of the second member 20 that has detached from the adsorber 1140 and the portion of the first member 10 corresponding thereto, the portion of the second member 20 that has been detached from the adsorber 1140 may be attached to the first member 10. For example, the adsorber 1140 may adsorb the second member 20 until just before the attaching of the second member 20 to the first member 10 is completed. Accordingly, right before the attaching of the second member 20 to the first member 10 is completed, the second member 20 may be disposed at a preset position.

In a comparative example, to seat the second member 20 on the second seat portion 1120 and dispose the second member 20 at the preset position, a vacuum adsorption hole configured to vacuum-adsorb the second member 20 may be disposed in a surface of the second seat portion 1120 on which the second member 20 is seated. When the roller portion 1130 and the second seat portion 1120 move under the second member 20, the degree of vacuum of the vacuum adsorption hole may be reduced. When the degree of vacuum of the vacuum adsorption hole is reduced, the position of the second member 20 on the second seat portion 1120 may be moved by moving the second seat portion 1120.

When the degree of vacuum of the vacuum adsorption hole is reduced, the second member 20 may not be disposed at the preset position on the second seat portion 1120. For example, because the adsorption force of the second seat portion 1120 with respect to the second member 20 is reduced, the second member 20 may detach from the second seat portion 1120. Accordingly, a portion of the second member 20 may contact a portion except (or other than) the portion of the first member 10 set in advance, and thus, air bubbles may be formed between the first member 10 and the second member 20. Because air bubbles cause stains on the display apparatus, display quality may be reduced. That is, defects may occur during the manufacturing process. In addition, when the second member 20 is rigid, because adsorption force of the second seat portion 1120 with respect to the second member 20 is reduced, the second member 20 may be more easily detached from the second seat portion 1120.

However, in the method of manufacturing the display apparatus according to an embodiment of the present disclosure, the adsorber 1140 may adsorb the second member. The adsorber 1140 may move inside the rail groove 1120G, and the rail groove 1120G may be disposed on one surface of the second seat portion 1120 facing the first seat portion 1110. Accordingly, when the second seat portion 1120 moves under the second member 20 together with the moving of the roller portion 1130, the adsorber 1140 may move in the direction from the first inner side IS1 to the second inner side IS2 inside the rail groove 1120G. Accordingly, even though the second seat portion 1120 moves, adsorption force of the adsorber 1140 with respect to the second member 20 may not be reduced (e.g., the adsorption force may be maintained).

Accordingly, the second member 20 may be disposed at a preset position on the second seat portion 1120 and may a portion of the second member 20 may not contact a portion except the portion of the first member 10 determined in advance. For example, a possibility that defects occur during the manufacturing process may be reduced. In addition, because adsorption force of the adsorber 1140 with respect to the second member 20 is not reduced even though the second member 20 is rigid, the second member 20 may be disposed at the preset position on the second seat portion 1120. Because the adsorber 1140 adsorbs the second member 20 until just before the attaching of the second member 20 to the first member 10 is completed, a possibility that defects occur during the manufacturing process may be reduced even more.

As described above, when the second member 20 is attached to the first member 10 to complete the manufacturing of the display apparatus, the display apparatus may be separated from the first seat portion 1110 and transferred to a different position (e.g., a different station). Thereafter, another first member 10 is disposed under the first seat portion 1110, another second member 20 is disposed on the second seat portion 1120, and the above process is repeatedly performed to manufacture another display apparatus.

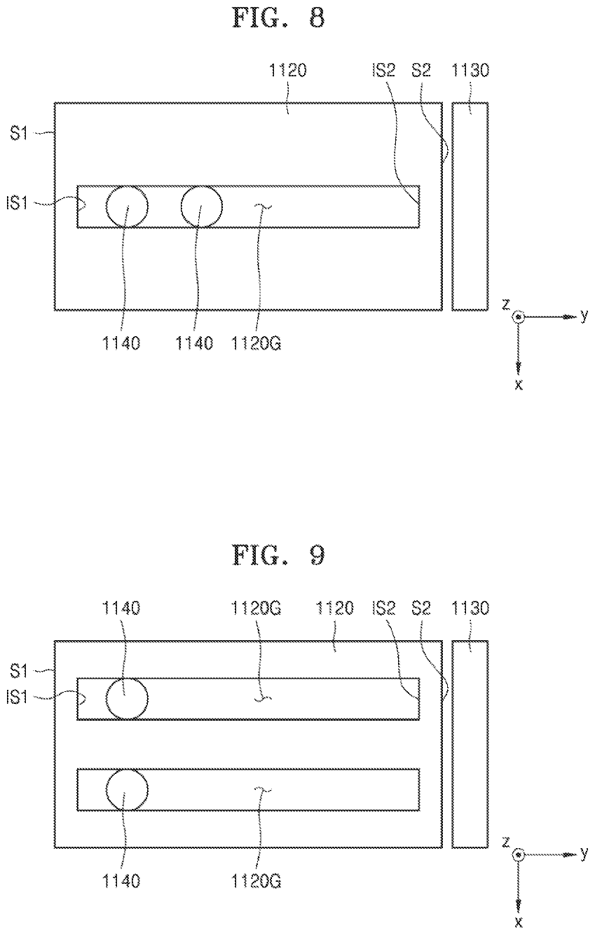

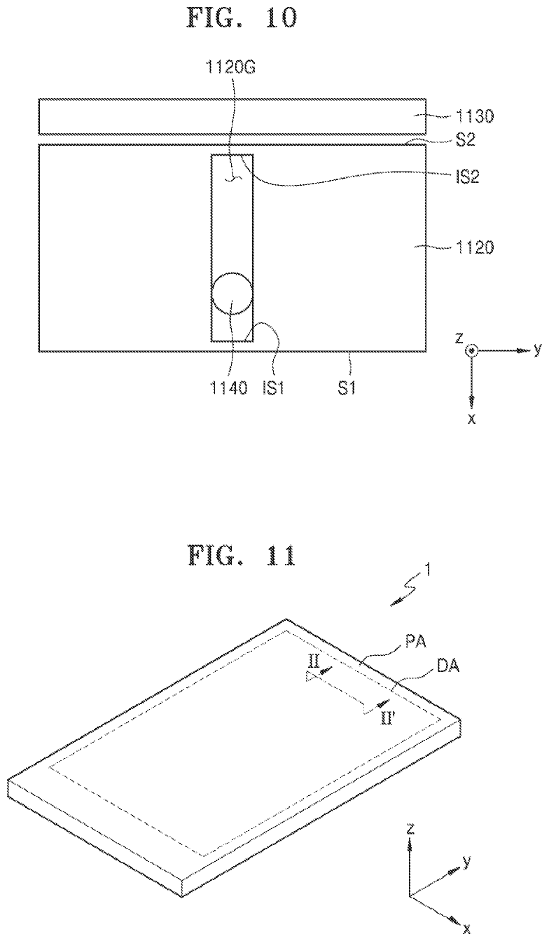

FIG. 8 is a schematic plan view of an apparatus 1000 for manufacturing a display apparatus according to another embodiment. FIG. 9 is a schematic plan view of an apparatus 1000 for manufacturing a display apparatus according to another embodiment. FIG. 10 is a schematic plan view of an apparatus 1000 for manufacturing a display apparatus according to another embodiment. For convenience of illustration, FIGS. 8 to 10 show only the second seat portion 1120, the roller portion 1130, and the adsorber 1140 of the various embodiments of the apparatus 1000. Because apparatuses 1000 for manufacturing the display apparatus according to these embodiments are similar to the apparatus 1000 for manufacturing the display apparatus described above with reference to FIGS. 1 to 3, differences from the apparatus 1000 for manufacturing the display apparatus described above with reference to FIGS. 1 to 3 are primarily described below.

The adsorber 1140 shown in FIG. 8 may be disposed in (e.g., arranged in) the rail groove 1120G. The apparatus 1000 for manufacturing the display apparatus according to the embodiment described above with reference to FIGS. 1 to 3 includes one adsorber 1140. However, the apparatus 1000 for manufacturing the display apparatus according to the embodiment shown in FIG. 8 includes a plurality of adsorbers 1140. For example, in the apparatus 1000 for manufacturing the display apparatus according to the embodiment shown in FIG. 8, the plurality of adsorbers 1140 may be disposed inside the rail groove 1120G. In one embodiment, the plurality of adsorbers 1140 may be apart from each other inside the rail groove (e.g., the same rail groove) 1120G in an extending direction of the rail groove 1120G. As an example, the plurality of adsorbers 1140 may be apart from each other inside the rail groove 1120G in the second direction (e.g., they direction or the −y direction).

As described above, the adsorber 1140 may adsorb the second member 20, and thus, the second member 20 may be disposed on the second seat portion 1120. Because the apparatus 1000 for manufacturing the display apparatus according to some embodiments includes the plurality of adsorbers 1140, an area of the second member 20 adsorbed by the adsorber 1140 is increased. Accordingly, adsorption force of the adsorber 1140 with respect to the second member 20 may be increased, and adsorption force may be more uniformly dispersed. Accordingly, during a process of attaching the second member 20 to the first member 10, a possibility that the second member 20 is detached from the second seat portion 1120 may be reduced even further.

The rail groove 1120G shown in FIG. 9 may be disposed in one surface of the second seat portion 1120 (e.g., may be offset from a center of the second seat portion 1120), and the adsorber 1140 may be disposed inside the rail groove 1120G. The apparatus 1000 for manufacturing the display apparatus according to the embodiment described above with reference to FIGS. 1 to 3 includes one adsorber 1140 and one rail groove 1120G. However, the apparatus 1000 for manufacturing the display apparatus according to the embodiment shown in FIG. 9 includes a plurality of adsorbers 1140 and a plurality of rail grooves 1120G. For example, in the apparatus 1000 for manufacturing the display apparatus according to the embodiment shown in FIG. 9, the plurality of adsorbers 1140 may each be disposed inside the plurality of rail groove 1120G. The plurality of rail grooves 1120G may be apart from each other in a direction crossing the extending direction of the rail groove 1120G and may be disposed in one surface of the second seat portion 1120. As an example, the plurality of rail grooves 1120G may be spaced apart from each other in the first direction (e.g., the x direction or the −x direction) and may be disposed in one surface of the second seat portion 1120. At least one adsorber 1140 may be disposed inside each of the plurality of rail grooves 1120G. Though it is shown in FIG. 9 that one adsorber 1140 is disposed inside one rail groove 1120G, the present disclosure is not limited thereto. As an example, similar to the rail groove 1120G and the adsorber 1140 shown in FIG. 8, a plurality of adsorbers 1140 may be disposed inside each of the rail grooves 1120G.

As described above, the adsorber 1140 may adsorb the second member 20, and thus, the second member 20 may be disposed on the second seat portion 1120. Because the apparatus 1000 for manufacturing the display apparatus according to an embodiment includes a plurality of adsorbers 1140 in different rail grooves 1120G, the area of the second member 20 adsorbed by the adsorber 1140 is increased. Accordingly, adsorption force of the adsorber 1140 with respect to the second member 20 may be increased, and adsorption force may be more uniformly dispersed. Accordingly, during a process of attaching the second member 20 to the first member 10, a possibility that the second member 20 is detached from the second seat portion 1120 may be reduced even more.

The adsorber 1140 shown in FIG. 10 may be disposed in the rail groove 1120G. The apparatus 1000 for manufacturing the display apparatus according to the embodiment described with reference to FIGS. 1 to 3 includes the rail groove 1120G extending in the second direction (e.g., the y direction or the −y direction). However, the apparatus 1000 for manufacturing the display apparatus according to the embodiment shown in FIG. 10 includes the rail groove 1120G extending in the first direction (e.g., the x direction or the −x direction). In such an embodiment, the roller portion 1130 may extend in the second direction (e.g., the y direction or the −y direction) and may move in the first direction (e.g., the x direction or the −x direction). Thus, even in this embodiment, the rail groove 1120G may extend in the same direction as the moving direction of the roller portion 1130.

The moving direction of the roller portion 1130 under the second member 20 may change depending on the configuration included in the second member 20 and the position of the configuration. Accordingly, the extending direction of the rail groove 1120G may change depending on the moving direction of the roller portion 1130, and the extending direction of the rail groove 1120G may be the same as the moving direction of the roller portion 1130. Accordingly, the adsorber 1140 may adsorb the second member 20 regardless of the configuration of the second member 20 and the position of the configuration. Accordingly, during a process of attaching the second member 20 to the first member 10, a possibility that the second member 20 is detached from the second seat portion 1120 may be reduced.

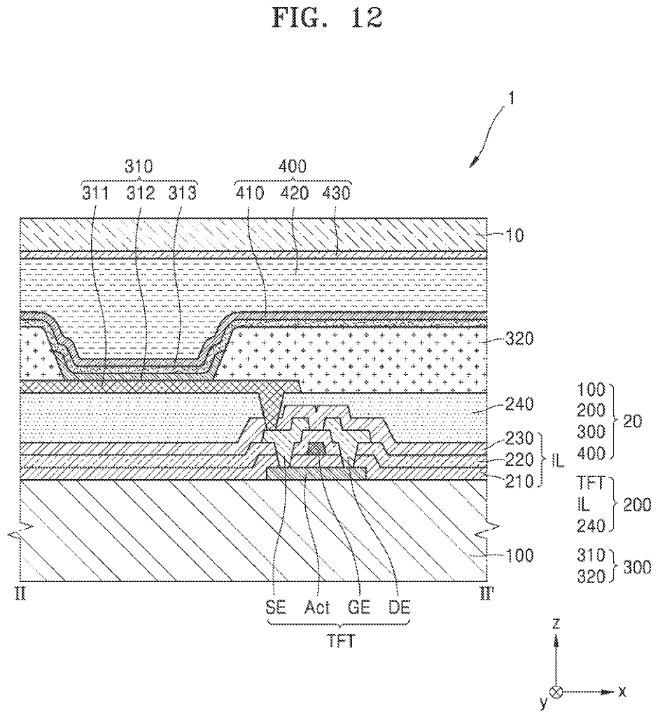

FIG. 11 is a schematic perspective view of a portion of a display apparatus manufactured by the apparatus 1000 for manufacturing a display apparatus according to an embodiment, and FIG. 12 is a schematic cross-sectional view of the display apparatus 1 taken along the line II-II′ of FIG. 11.

As shown in FIG. 11, the display apparatus 1 may have a display area DA and a peripheral area PA. A plurality of pixels are arranged in the display area DA, and the peripheral area PA is outside (e.g., extend around) the display area DA. For example, the peripheral area PA may entirely surround (e.g., may surround in a plan view or may extend around a periphery of) the display area DA. It may be understood that a substrate 100 included in the display apparatus has the display area DA and the peripheral area PA.

Each pixel of the display apparatus 1 is a region that may emit light of a certain color. The display apparatus 1 may be configured to display images by using light from the pixels. As an example, each pixel may be configured to emit red light, green light, or blue light.

As shown in FIG. 1, the display area DA may have a polygonal shape, such as a quadrangular shape. As an example, the display area DA may have a rectangular shape in which a horizontal length thereof is greater than a vertical length, a rectangular shape in which a horizontal length thereof is less than a vertical length, or a square shape. However, the display area DA may have various shapes, such as an elliptical shape or a circular shape.

The peripheral area PA may be a non-display area in which the pixels are not arranged. A driver and the like configured to provide electric signals or power to the pixels may be arranged in the peripheral area PA. Pads may be arranged in the peripheral area PA, and various kinds of electronic elements or a printed circuit board may be electrically connected to the pads. The pads may be apart (e.g., spaced apart) from each other in the peripheral area PA and electrically connected to a printed circuit board or an integrated circuit element.

As shown in FIG. 12, the display apparatus 1 may include the first member and the second member 20. As an example, the first member 10 may include a cover window, and the second member 20 may include a display panel. Hereinafter, for convenience of description, an embodiment in which the first member 10 and the second member 20 are the cover window and the display panel, respectively, is primarily described in detail. The second member 20 may be disposed below the first member 10. The second member 20 may be configured to display images. Images displayed by the second member 20 may be provided to users through the first member 10, which is transparent. For example, it may be understood that images displayed by the display apparatus 1 are implemented by (e.g., emitted by or from) the second member 20.

As shown in FIG. 12, the second member 20 may include the substrate 100, a pixel circuit layer 200, a display element layer 300, and an encapsulation layer 400. The pixel circuit layer 200 may be disposed on the substrate 100. The substrate 100 may include various flexible or bendable materials. As an example, the substrate 100 may include glass, metal, or a polymer resin. In addition, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers, each including the polymer resin, and a barrier layer including an inorganic material, such as silicon oxide, silicon nitride, and silicon oxynitride, therebetween. However, various modifications may be made therein.

The pixel circuit layer 200 may include a thin-film transistor TFT, an insulating layer IL, and a planarization layer 240. As shown in FIG. 12, the thin-film transistor TFT may include a semiconductor layer Act, a gate electrode GE, a source electrode SE, and a drain electrode DE. The semiconductor layer Act may include amorphous silicon, polycrystalline silicon, an oxide semiconductor material, or an organic semiconductor material. The insulating layer IL may include a gate insulating layer 210, a first interlayer insulating layer 220, and a second interlayer insulating layer 230. To secure insulation between the semiconductor layer Act and the gate electrode GE, the gate insulating layer 210 may be disposed between the semiconductor layer Act and the gate electrode GE. The gate insulating layer 210 includes an inorganic material, such as silicon oxide, silicon nitride, and/or silicon oxynitride. The first interlayer insulating layer 220 may be disposed on the gate electrode GE, and the first interlayer insulating layer 220 includes an inorganic material, such as silicon oxide, silicon nitride, and/or silicon oxynitride. The second interlayer insulating layer 230 may be disposed to cover the source electrode SE and the drain electrode DE. The insulating layer IL including the inorganic material may be formed by using chemical vapor deposition (CVD) or atomic layer deposition (ALD). The planarization layer 240 may be disposed on the thin-film transistor TFT. The planarization layer 240 may generally planarize the upper surface of the thin-film transistor TFT. The planarization layer 240 may include, for example, acryl, benzocyclobutene (BCB), or hexamethyldisiloxane (HMDSO). Although the planarization layer 240 is shown in FIG. 12 as a single layer, the planarization layer 240 may be a multi-layer. However, various modifications may be made therein.

The display element layer 300 may be disposed on the pixel circuit layer 200. The display element layer 300 may include a display element 310 and a pixel-defining layer 320, and the display element 310 is electrically connected to the thin-film transistor TFT. The display element 310 may be an organic light-emitting diode including a pixel electrode 311, an opposite electrode 313, and an intermediate layer 312. The intermediate layer 312 is disposed between the pixel electrode 311 and the opposite electrode 313 and includes an emission layer. When the display element 310 is electrically connected to the thin-film transistor TFT, it may be understood that the pixel electrode 311 of the display element 310 is electrically connected to the thin-film transistor TFT.

As shown in FIG. 12, the pixel electrode 311 is electrically connected to the thin-film transistor TFT by contacting one of the source electrode SE and the drain electrode DE through an opening formed in the planarization layer 240 and the like. The pixel electrode 311 includes a light-transmissive conductive layer and a reflective layer. The light-transmissive conductive layer includes a light-transmissive conductive oxide, such as indium tin oxide (ITO), indium oxide (In₂O₃), or indium zinc oxide (IZO), and the reflective layer includes metal, such as aluminum (Al) or silver (Ag). As an example, the pixel electrode 311 may have a three-layered structure of ITO/Ag/ITO.

The pixel-defining layer 320 may be disposed on the planarization layer 240. The pixel-defining layer 320 defines a pixel by having an opening corresponding to each pixel, that is, an opening exposing at least a central portion of the pixel electrode 311. In addition, as shown in FIG. 12, the pixel-defining layer 320 prevents arcs and the like from occurring at the edges of the pixel electrode 311 by increasing a distance between the edges of the pixel electrode 311 and the opposite electrode 313 over the pixel electrode 311. The pixel-defining layer 320 may include an organic material, such as polyimide or HMDSO.

The intermediate layer 312 of the display element 310 may include a low-molecular weight material or a polymer material. When the intermediate layer 312 includes a low molecular weight material, the intermediate layer 312 may have a structure in which a hole injection layer (HIL), a hole transport layer (HTL), an emission layer (EML), an electron transport layer (ETL), an electron injection layer (EIL), etc. are stacked in a single or composite configuration. The intermediate layer 312 may be formed by vacuum deposition. When the intermediate layer 312 includes a polymer material, the intermediate layer 312 may have a structure including an HTL and an EML. In such an embodiment, the HTL may include poly (3,4-ethylenedioxythiophene) (PEDOT), and the EML may include a polymer material, such as a polyphenylene vinylene (PPV)-based material and a polyfluorene-based material. The intermediate layer 312 may be formed by screen printing, inkjet printing, laser induced thermal imaging (LITI), or the like. The intermediate layer 312 is not necessarily limited thereto and may have various suitable structures. In addition, the intermediate layer 312 may include a layer, which is one body over the plurality of pixel electrodes 311, or may include a layer patterned to correspond to each of the plurality of pixel electrodes 311.

The opposite electrode 313 may be formed as one body over (e.g., entirely over or over all of) the plurality of display elements 310 to correspond to the plurality of pixel electrodes 311. The opposite electrode 313 may include a light-transmissive conductive layer including indium tin oxide (ITO), indium oxide (In₂O₃), or indium zinc oxide (IZO) and may include a semi-transmissive layer including metal, such as aluminum (Al) or silver (Ag). As an example, the opposite electrode 313 may be a semi-transmissive layer including magnesium (Mg) and silver (Ag).

The encapsulation layer 400 may be disposed on the display element layer 300. Because the display element 310 may be easily damaged by external moisture, oxygen, or the like, the encapsulation layer 400 may protect the display element 310 by covering the display element 310. As shown in FIG. 12, the encapsulation layer 400 may include a first inorganic encapsulation layer 410, an organic encapsulation layer 420, and a second inorganic encapsulation layer 430.

The first inorganic encapsulation layer 410 may cover the opposite electrode 313 and may include silicon oxide, silicon nitride, and/or silicon oxynitride. When needed, other layers including a capping layer may be disposed between the first inorganic encapsulation layer 410 and the opposite electrode 313. Because the first inorganic encapsulation layer 410 is formed along a structure thereunder, the upper surface of the first inorganic encapsulation layer 410 is not flat as shown in FIG. 12. The organic encapsulation layer 420 may cover the first inorganic encapsulation layer 410 and, different from the first inorganic encapsulation layer 410, the upper surface of the organic encapsulation layer 420 may be approximately or substantially flat. The organic encapsulation layer 420 may include at least one material from among polyethylene terephthalate, polyethylene naphthalate, polycarbonate, polyimide, polyethylene sulfonate, polyoxymethylene, polyarylate, and hexamethyldisiloxane. The second inorganic encapsulation layer 430 may cover the organic encapsulation layer 420 and may include silicon oxide, silicon nitride, and/or silicon oxynitride.

Because the encapsulation layer 400 includes the first inorganic encapsulation layer 410, the organic encapsulation layer 420, and the second inorganic encapsulation layer 430, even when cracks occur inside the encapsulation layer 400, the cracks may not be connected (e.g., may not extend) between the first inorganic encapsulation layer 410 and the organic encapsulation layer 420 or between the organic encapsulation layer 420 and the second inorganic encapsulation layer 430 through the above multi-layered structure. With this configuration, formation of a path through which external moisture or oxygen penetrates into the inside of the display apparatus 1 may be prevented or reduced.

The first member 10 may be disposed on the second member 20. The first member 10 may be disposed to cover the upper surface of the second member 20. The first member 10 may be configured to protect the upper surface of the second member 20. In addition, because the cover window forms the appearance of the display apparatus 1, the cover window may include a plane and a curved surface corresponding to the shape of the display apparatus 1.

The first member 10 may have a high transmittance to transmit light emitted from the second member 20 and may have a thin thickness to reduce the weight of the display apparatus 1. The first member 10 may be configured to protect the second member 20 while easily bending according to an external force without cracking. The first member 10 may have a flexible window. The first member 10 may be attached to the second member 20 by an adhesive layer. The adhesive layer may include an adhesive member, such as an optical clear adhesive (OCA) or a pressure sensitive adhesive (PSA).

A protective film may be disposed under the second member 20 to face the lower surface (e.g., in a −z direction) of the second member 20. For example, the protective film may be disposed under the substrate 100 to face the lower surface (e.g., in the −z direction) of the substrate 100. The protective film may be configured to protect the second member 20 during the process of manufacturing the display apparatus. An adhesive layer may be disposed between the protective film and the substrate 100. The protective film may be attached under the substrate 100 by the adhesive layer. The adhesive layer disposed between the protective film and the substrate 100 may include at least one of an optical clear resin (OCR), an optical clear adhesive (OCA), and a pressure sensitive adhesive (PSA).

According to an embodiment, the display apparatus has a reduced defect occurrence possibility during a manufacturing process, and the method of manufacturing the display apparatus may be implemented. However, the scope of the present disclosure is not limited to these aspects and features.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. An apparatus for manufacturing a display apparatus, the apparatus comprising:
a first seat portion configured to receive a first member;
a second seat portion arranged to face the first seat portion and configured to receive a second member;
a roller portion adjacent to a second side of the second seat portion;
a rail groove in one surface of the second seat portion facing the first seat portion; and
an adsorber inside the rail groove and configured to adsorb the second member.

2. The apparatus of claim 1, wherein the second seat portion has a first side and the second side, the first side being arranged in an opposite direction of the roller portion, and the second side being arranged in a direction of the roller portion, and
wherein the rail groove extends in a direction from the first side to the second side.

3. The apparatus of claim 1, wherein the rail groove has a first inner side and a second inner side, the first inner side being arranged in an opposite direction of the roller portion, and the second inner side being arranged in a direction of the roller portion.

4. The apparatus of claim 3, wherein the adsorber is configured to move in a direction from the first inner side to the second inner side.

5. The apparatus of claim 4, wherein, when the adsorber contacts the second inner side, the adsorber is configured to detach from the second member.

6. The apparatus of claim 3, wherein the adsorber is configured to slide in a direction from the first inner side to the second inner side.

7. The apparatus of claim 1, wherein the roller portion extends in a first direction and is configured to move in a second direction crossing the first direction under the second member, and
wherein the rail groove extends in the second direction.

8. The apparatus of claim 7, wherein the second seat portion is configured to move in the second direction under the second member.

9. The apparatus of claim 1, wherein the roller portion extends in a first direction,
wherein the adsorber is provided in plurality, and
wherein the plurality of adsorbers are spaced apart from each other in the first direction and arranged inside the rail groove.

10. The apparatus of claim 1, wherein the roller portion extends in a first direction,
wherein the rail groove is provided in plurality,
wherein the plurality of rail grooves are spaced apart from each other in a second direction crossing the first direction and are in the one surface of the second seat portion facing the first seat portion,
wherein the adsorber is provided in plurality, and
wherein each of the plurality of adsorbers is inside the plurality of rail grooves.

11. A method of manufacturing a display apparatus, the method comprising:
arranging a first member under a first seat portion;
arranging a second member on a second seat portion to face the first seat portion;
adsorbing the second member onto an adsorber inside a rail groove in the second seat portion;
tilting the second seat portion to form an angle with respect to the first seat portion; and
attaching the second member to the first member by pressing the second member by using a roller portion, the adsorber moving along the rail groove as the second member is attached to the first member.

12. The method of claim 11, wherein the attaching of the second member includes pressing the first member and the second member while moving the roller portion under the second member.

13. The method of claim 12, further comprising moving the second seat portion under the second member in a same direction as a moving direction of the roller portion.

14. The method of claim 13, wherein the adsorber moves inside the rail groove as the second seat portion is moved.

15. The method of claim 12, wherein the rail groove extends in a same direction as a moving direction of the roller portion, and
wherein the rail groove has a first inner side and a second inner side, the first inner side being arranged in an opposite direction of the roller portion, the second inner side being arranged in a direction of the roller portion.

16. The method of claim 15, wherein the adsorber moves inside the rail groove in a direction from the first inner side to the second inner side along the rail groove.

17. The method of claim 15, wherein the adsorber slides along the rail groove in a direction from the first inner side to the second inner side of the rail groove.

18. The method of claim 11, further comprising detaching the second member from the adsorber; and
attaching a portion of the second member detached from the adsorber to the first member.

19. The method of claim 18, wherein the portion of the second member detached from the adsorber is attached to the first member after the adsorber has moved along the rail groove.

20. The method of claim 18, wherein the rail groove extends in a same direction as a moving direction of the roller portion in a plan view, and
wherein the rail groove has a first inner side and a second inner side, the first inner side being arranged in an opposite direction of the roller portion, and the second inner side being arranged in a direction of the roller portion, and
wherein the portion of the second member detached from the adsorber is attached to the first member after the adsorber contacts the second inner side.
